(19) United States
(12) Patent Application Publication
(10) Pub. No.: US 2020/0279089 A1
(43) Pub. Date: Sep. 3, 2020

(54) ULTRASONIC TRANSDUCER DEVICE, ACOUSTIC BIOMETRIC IMAGING SYSTEM AND MANUFACTURING METHOD

(71) Applicant: FINGERPRINT CARDS AB, Göteborg (SE)

(72) Inventors: Karl LUNDAHL, GÖTEBORG (SE); Hanna NILSSON, GÖTEBORG (SE); Martin GRIP, HÖLLVIKEN (SE)

(73) Assignee: FINGERPRINT CARDS AB, Göteborg (SE)

(21) Appl. No.: 16/645,959

(22) PCT Filed: Sep. 17, 2018
(86) PCT No.: PCT/SE2018/050937

§ 371 Date: Mar. 10, 2020

(30) Foreign Application Priority Data
Sep. 22, 2017 (SE) 1751184-1

(51) Int. Cl. G06K 9/00; H01L 41/047; H01L 41/311; B06B 1/06

(52) U.S. Cl. CPC G06K 9/0002; B06B 1/0622; H01L 41/311; H01L 41/0475

(57) ABSTRACT

A method of manufacturing ultrasonic transducer devices, comprising fabricating an ultrasonic transducer panel; and dividing the ultrasonic transducer panel into ultrasonic transducer devices. Fabricating the ultrasonic transducer panel includes: providing a first carrier; arranging a plurality of piezoelectric elements spaced apart on the first carrier; applying a dielectric material on the plurality of piezoelectric elements to embed each piezoelectric element in the plurality of piezoelectric elements in the dielectric material, thereby forming a piezoelectric element device layer on the first carrier; thinning the piezoelectric element device layer, resulting in an exposed first side of each piezoelectric element in the plurality of piezoelectric elements; forming a first electrode layer on the piezoelectric element device layer, the first electrode layer including a first transducer electrode on the exposed first side of each piezoelectric element in the piezoelectric element device layer; and separating the piezoelectric element device layer from the first carrier.

### FIELD OF THE INVENTION

The present invention relates to ultrasonic transducer devices for use in an acoustic biometric imaging system, and a method of manufacturing such ultrasonic transducer devices.

### BACKGROUND OF THE INVENTION

Biometric systems are widely used as means for increasing the convenience and security of personal electronic devices, such as mobile phones etc. Fingerprint sensing systems, in particular, are now included in a large proportion of all newly released personal communication devices, such as mobile phones.

Due to their excellent performance and relatively low cost, capacitive fingerprint sensors are used in an overwhelming majority of all biometric systems.

Among other fingerprint sensing technologies, ultrasonic sensing also has the potential to provide advantageous performance, such as the ability to acquire fingerprint (or palmprint) images from very moist fingers etc.

One class of ultrasonic fingerprint systems of particular interest are systems in which acoustic signals are transmitted along a surface of a device member to be touched by a user, and a fingerprint (palm print) representation is determined based on received acoustic signals resulting from the interaction between the transmitted acoustic signals and an interface between the device member and the user's skin.

Such ultrasonic fingerprint sensing systems, which are, for example, generally described in US 2017/0053151 may provide for controllable resolution, and allow for a larger sensing area, which may be optically transparent, without the cost of the fingerprint sensing system necessarily scaling with the sensing area.

Although the general principle of such ultrasonic fingerprint sensing is known, there appear to be remaining challenges to be overcome. For instance, it would be desirable to provide for cost-efficient mass production of ultrasonic transducer devices suitable for use in such ultrasonic fingerprint sensing systems.

### SUMMARY

In view of above-mentioned and other drawbacks of the prior art, it is an object of the present invention to provide for cost-efficient mass production of improved ultrasonic transducer devices.

According to a first aspect of the present invention, it is therefore provided a method of manufacturing ultrasonic transducer devices for use in an acoustic biometric imaging system, comprising the steps of: fabricating an ultrasonic transducer panel; and dividing the ultrasonic transducer panel into the ultrasonic transducer devices. The step of fabricating the ultrasonic transducer panel comprises the steps of: providing a first carrier; arranging a plurality of piezoelectric elements spaced apart on the carrier; applying a dielectric material on the plurality of piezoelectric elements to embed each piezoelectric element in the plurality of piezoelectric elements in the dielectric material, thereby forming a piezoelectric element device layer on the first carrier; thinning the piezoelectric element device layer, resulting in an exposed first side of each piezoelectric element in the plurality of piezoelectric elements; forming a first electrode layer on the piezoelectric element device layer, the first electrode layer including a first transducer electrode on the exposed first side of each piezoelectric element in the piezoelectric element device layer; and separating the piezoelectric element device layer from the first carrier.

The first carrier may be any carrier suitable for the fabrication process, and may include any carrier used in so-called wafer level fan-out processes, or in panel production processes (such as for thin film electronics). The first carrier may, for example, include a relatively rigid base covered by a temporary bond film (carrier tape). The relatively rigid base may be made of any material compatible with the particular fabrication process, and may thus, for instance, be made of silicon, glass, polymer or metal.

The dielectric material embedding the piezoelectric elements on the first carrier may, as will be known to one skilled in the art, be any dielectric embedding material suitable for the particular fabrication process. Accordingly, the dielectric material may be a molding material that may, for example be provided in granular or liquid form. Alternatively, the dielectric material may be provided in the form of a film that is laminated on the piezoelectric elements arranged on the first carrier.

The thinning step may be carried out by removing material from the piezoelectric element device layer, including from each piezoelectric element and from the dielectric material embedding each piezoelectric element. Various thinning methods that are, per se, well known include grinding, polishing/lapping, and etching.

The first electrode layer may be formed using any suitable process, such as metallization by, for example, sputtering or CVD. Alternatively, sputtering or CVD may be used for forming a seed layer for subsequent electroplating.

It should be noted that the steps of the method according to embodiments of the present invention may not necessarily need to be carried out in a particular order. For instance, the step of dividing the ultrasonic transducer panel into the ultrasonic transducer devices may be carried out before or after the step of separating the piezoelectric element device layer from the first carrier.

The present invention is based upon the realization that ultrasonic transducer devices with thin and mechanically protected piezoelectric elements can be manufactured using a process including embedding and thinning piezoelectric elements when the piezoelectric elements are arranged spaced apart on a temporary carrier.

Embodiments of the method according to the present invention are thus suitable for inexpensive, high-yield, mass production of very small and thin ultrasonic transducer devices, particularly suitable for fingerprint sensing applications.

Since the exposed first side of each piezoelectric element results from the thinning process, a very smooth surface of the first side of each piezoelectric element can be achieved. This in turn enables the use of a very thin first transducer electrode for reliably controlling operation of the ultrasonic transducer device. The use of a thin first transducer electrode may allow for improved acoustic coupling of the ultrasonic transducer device to a device member, which may in turn allow for the use of relatively high acoustic frequencies, which is expected to be beneficial for sensing fine features, such as fingerprint features.

In various embodiments of the method according to the present invention, the step of fabricating the ultrasonic transducer panel may further comprise the steps of: sandwiching the piezoelectric element device layer and the first electrode layer between the first carrier and a second carrier; and forming, after separating the piezoelectric element device layer from the first carrier, a second electrode layer on the piezoelectric element device layer, the second electrode layer including a second transducer electrode on a second side, opposite the first side, of each piezoelectric element in the piezoelectric element device layer.

The step of fabricating the ultrasonic transducer panel may further comprise the step of: thinning the piezoelectric element device layer, after separating the piezoelectric element device layer from the first carrier and before forming the second electrode layer.

As an alternative to processing on both sides of the ultrasonic transducer panel, the piezoelectric elements may be metallized before attachment to the first carrier, and arranged on the first carrier with a metallized side facing the first carrier.

Furthermore, a plurality of conductive vias may advantageously be provided through the piezoelectric element layer. Such conductive vias may, for example, be provided as via components arranged on the first carrier and embedded together with the piezoelectric elements. Alternatively, or in combination, conductive vias may be provided by forming holes through the dielectric material embedding the piezoelectric elements, and thereafter depositing conducting material, such as metal, in the holes.

In embodiments, conductive vias extending through the piezoelectric element layer may advantageously be used to enable electrical connection to opposite sides of the piezoelectric elements from one side of the ultrasonic transducer device. To that end, conductive vias may be conductively connected to a transducer electrode of each piezoelectric element in the ultrasonic transducer panel.

The possibility to electrically connect to opposite sides of the piezoelectric element(s) comprised in each ultrasonic transducer device from one side of the ultrasonic transducer element is expected to be advantageous for the manufacturing process and performance an acoustic biometric imaging system including one or several ultrasonic transducer devices. For example, there may be no need to make conductive patterns on and conductively connect control circuitry etc to a device member (such as a cover glass) to be acoustically coupled to the piezoelectric elements of the ultrasonic transducer device(s). This allows for the use of a non conductive adhesive material for attaching and acoustically coupling the ultrasonic transducer device to a device member, such as a cover glass. This, in turn, may allow for improved acoustic coupling to the device member, especially when the device member is made of glass.

According to various embodiments, furthermore, the step of fabricating the ultrasonic transducer panel may further comprise the step of: forming, after the step of forming the first electrode layer, a spacer structure leaving at least a portion of each of the first transducer electrodes uncovered (by the spacer structure).

Such a spacer structure, which may advantageously be a dielectric spacer structure, may provide for a uniform distance between the piezoelectric element(s) comprised in the ultrasonic transducer device and the surface of a device member (such as a cover glass) to be acoustically coupled to the piezoelectric elements of the ultrasonic transducer device(s). This is expected to be particularly advantageous for embodiments in which the ultrasonic transducer device comprises a plurality of piezoelectric elements, such as a linear array of piezoelectric elements.

According to embodiments, the ultrasonic transducer panel may be divided by cutting through the dielectric material embedding the plurality of piezoelectric elements, in such a way that dielectric material covering the edges of the piezoelectric element(s) remains after the cutting step. The term “cutting” should be understood to generally represent any way of removing dielectric material between neighboring piezoelectric elements, and includes, for example, mechanical sawing or scribing, laser cutting, water jet cutting, and etching etc.

By dividing the ultrasonic transducer panel in this manner, it can be ensured that the edges of the piezoelectric element(s) comprised in the ultrasonic transducer devices are protected, which may make the ultrasonic transducer devices more robust, and suitable for standard high volume electronics manufacturing methods, such as so-called pick-and-place.

According to a second aspect of the present invention, there is provided an ultrasonic transducer device for use in an acoustic biometric imaging system, the ultrasonic transducer device comprising: a piezoelectric element having a first face, a second face opposite the first face, and side edges extending between the first face and the second face; a first transducer electrode on the first face of the piezoelectric element; a second transducer electrode on the second face of the piezoelectric element; and a dielectric material embedding the piezoelectric element in such a way that the side edges are completely covered by the dielectric material.

According to embodiments, at least one of the first transducer electrode and the second transducer electrode may partly cover the dielectric material embedding the piezoelectric element.

According to embodiments, furthermore, the dielectric material embedding the piezoelectric element may be co-planar with the first face of the piezoelectric element, at least at the side edges of the piezoelectric element.

Advantageously, the dielectric material embedding the piezoelectric element and the piezoelectric element may have been thinned in the same thinning process.

According to various embodiments, the ultrasonic transducer device may comprise a plurality of piezoelectric elements, each having a first face, a second face opposite the first face, and side edges extending between the first face and the second face; a first transducer electrode on the first face of each piezoelectric element in the plurality of the piezoelectric elements; a second transducer electrode on the second face of each piezoelectric element in the plurality of the piezoelectric elements; and an integrated circuit electrically connected to at least one of the first transducer electrode and the second transducer electrode of each piezoelectric element in the plurality of piezoelectric elements, wherein the dielectric material embeds the integrated circuit, and embeds the plurality of piezoelectric element in such a way that the side edges of each piezoelectric element in the plurality of the piezoelectric elements are completely covered by the dielectric material.

The ultrasonic transducer device according to embodiments of the present invention may, furthermore, advantageously be included in an acoustic biometric imaging system, further comprising a controller connected to the at least one ultrasonic transducer and being configured to: receive, from the at least one ultrasonic transducer, electrical signals indicative of acoustic signals conducted by a device member and acoustically coupled to the at least one ultrasonic transducer; and form a representation of the finger surface based on the received electrical signals.

Further embodiments of, and effects obtained through this second aspect of the present invention are largely analogous to those described above for the first aspect of the invention.

### BRIEF DESCRIPTION OF THE DRAWINGS

These and other aspects of the present invention will now be described in more detail, with reference to the appended drawings showing an example embodiment of the invention, wherein:

FIG. 1A is an illustration of an exemplary electronic device comprising an acoustic biometric imaging system according to an embodiment of the present invention, in the form of a mobile phone;

FIG. 1B is a schematic illustration of a first ultrasonic transducer device configuration in the electronic device in FIG. 1A;

FIG. 1C is a schematic illustration of a second ultrasonic transducer device configuration in the electronic device in FIG. 1A;

FIG. 2A is a schematic perspective view of one of the ultrasonic transducer devices in FIG. 1B;

FIG. 2B is an enlarged partial cross-section view of the ultrasonic transducer device in FIG. 2A;

FIG. 3 is a flow-chart illustrating an example embodiment of the manufacturing method according to the present invention; and

FIGS. 4A-G schematically illustrate the result of the respective method steps in the flow-chart in FIG. 3.

### DETAILED DESCRIPTION OF EXAMPLE EMBODIMENTS

In the present detailed description, various embodiments of the ultrasonic transducer device according to the present invention are mainly described with reference to an ultrasonic transducer device including a first piezoelectric element and a second piezoelectric element, each having first and second transducer electrodes that are both connectable from one side of the ultrasonic transducer device. It should be noted that ultrasonic transducer devices with many other configurations also fall within the scope defined by the claims. For instance, the ultrasonic transducer device may include fewer or more piezoelectric elements, and/or may additionally include on or more integrated circuits for driving the piezoelectric element(s) and/or sensing electrical signals provided by the piezoelectric element(s). Moreover, the first and second transducer electrodes may be connectable from different sides of the ultrasonic transducer device.

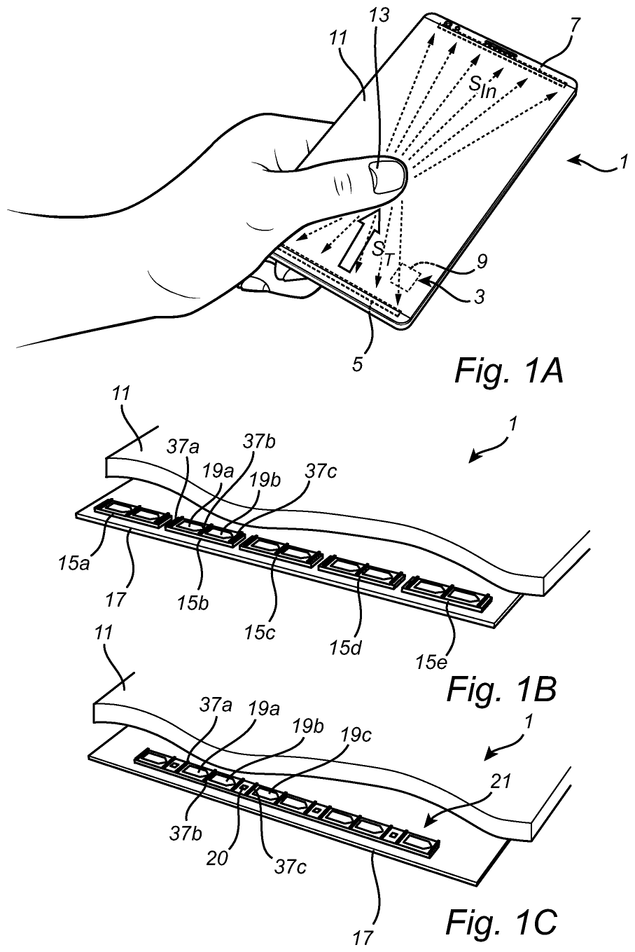

The acoustic biometric imaging system according to embodiments of the present invention may be included in various electronic devices. FIG. 1A schematically illustrates a representative electronic device, in the form of a mobile phone 1, comprising an acoustic biometric imaging system 3 according to an embodiment of the present invention.

As is schematically indicated in FIG. 1A, the acoustic biometric imaging system 3 comprises a first ultrasonic transducer array 5, a second ultrasonic transducer array 7, and a controller 9 connected to the first 5 and second 7 ultrasonic transducer arrays.

The first ultrasonic transducer array 5 and the second ultrasonic transducer array 7 are both acoustically coupled to a device member, here cover glass 11, of the electronic device 1 to be touched by the user. The user touch is indicated by the thumb 13 in FIG. 1A.

When the acoustic biometric imaging system 3 is in operation, the controller 9 controls one or several piezoelectric element(s) comprised in at least one of the first 5 and the second 7 ultrasonic transducer arrays to transmit an acoustic transmit signal S_{T}, indicated by the block arrow in FIG. 1A. Further, the controller 9 controls at least one of the first 5 and the second 7 ultrasonic transducer arrays to receive acoustic interaction signals Sᵢₙ, indicated by the dashed arrows in FIG. 1A. The acoustic interaction signals Sᵢₙ are indicative of interactions between the transmit signal S_{T} and the interface between the cover glass 11 and the skin of the user (thumb 13). The acoustic interaction signals Sᵢₙ are transformed to electrical signals by the receiving piezoelectric elements in the first 5 and/or second 7 ultrasonic transducer arrays, and the electrical signals are processed by the controller 9 to provide a representation of the fingerprint of the user.

The acoustic interaction signals Sᵢₙ are presently believed to mainly be due to so-called contact scattering at the contact area between the cover glass and the skin of the user (thumb 13).

The acoustic transmit signal S_{T} may advantageously be a pulse train of short pulses (impulses), and the acoustic interaction signals Sᵢₙ, which may be measured for different angles by different receiving piezoelectric elements, are impulse responses. The impulse response data carried by the acoustic interaction signals Sᵢₙ can be used to reconstruct a representation of the contact area (the fingerprint) using a reconstruction procedure similar to methods used in ultrasound reflection tomography.

It should be understood that the “representation” of the fingerprint of the user may be any information extracted based on the received acoustic interaction signals Sᵢₙ, which is useful for assessing the similarity between fingerprint representations acquired at different times. For instance, the representation may comprise descriptions of fingerprint features (such as so-called minutiae) and information about the positional relationship between the fingerprint features. Alternatively, the representation may be a fingerprint image, or a compressed version of the image. For example, the image may be binarized and/or skeletonized. Moreover, the fingerprint representation may be the above-mentioned impulse response representation.

FIG. 1B is a schematic illustration of a first ultrasonic transducer device configuration in the electronic device 1 in FIG. 1A, in which a plurality of ultrasonic transducer devices 15a-e are electrically and mechanically connected to a connector, here exemplified by a transducer substrate 17, and acoustically coupled to the device member (cover glass 11). In the example configuration shown in FIG. 1B, each ultrasonic transducer device 15a-e comprises a first 19a and a second 19b piezoelectric element (only indicated for one of the ultrasonic transducer devices in FIG. 1B to avoid cluttering the drawing). As is also schematically indicated in FIG. 1B, each ultrasonic transducer device 15a-e comprises spacer structures 37a-c, that are configured to define a distance between the piezoelectric elements 19a-b and the attachment surface of the cover glass 11. The spacer structures 37a-c, which may advantageously be dielectric spacer structures, are configured to allow any excess (conductive or non-conductive) adhesive or solder to escape from the area directly above the piezoelectric elements 19a-b when the ultrasonic transducer device 15a-e is pressed against the cover glass 11.

FIG. 1C is a schematic illustration of a second ultrasonic transducer device configuration in the electronic device 1 in FIG. 1A, in which an ultrasonic transducer array component 21 is electrically and mechanically connected to a connector, here exemplified by a transducer substrate 17, and acoustically coupled to the device member (cover glass 11). In the example configuration shown in FIG. 1C, the ultrasonic transducer array component 21 comprises eight piezoelectric elements 19a-c (only three of these are indicated by reference numerals in FIG. 1C to avoid cluttering the drawing). As is also schematically shown in FIG. 1C, the ultrasonic transducer array component 21 in FIG. 1C further comprises four integrated circuits 20 (again, only one of these is indicated in FIG. 1C), for interfacing with the piezoelectric elements 19a-c. The integrated circuits 20, may, for example be ultrasound driver circuits for driving at least one piezoelectric element with a relatively high voltage signal, such as 12 V or more, and/or ultrasound receiver circuits. The integrated circuit 20 indicated in FIG. 1C is connected to the piezoelectric elements 19b and 19c.

To be able to achieve high quality fingerprint representations, it is expected to be beneficial to use relatively high acoustic frequencies, and to provide for a good acoustic coupling between the piezoelectric elements comprised in the ultrasonic transducer devices and the device member to be touched by the user (such as the cover glass 11). By “good acoustic coupling” should be understood a mechanical coupling with a small damping and/or distortion of the acoustic signal at the interface between the piezoelectric element(s) and the device member to be touched by the user.

To provide for high acoustic frequencies, it is expected that the piezoelectric elements should be very thin, such as around 100 μm or less.

To provide for the desired good acoustic coupling, the present inventors have realized that the transducer electrode facing the device member to be touched by the finger should be as thin and smooth (low surface roughness) as possible. It is also expected that the mechanical joint between the piezoelectric element(s) and the device member to be touched by the finger should be as thin and stiff as possible, at least for the relevant acoustic frequencies, especially for chemically strengthened glass, such as so-called gorilla glass.

At the same time, the ultrasonic transducer devices should be suitable for cost-efficient mass-production.

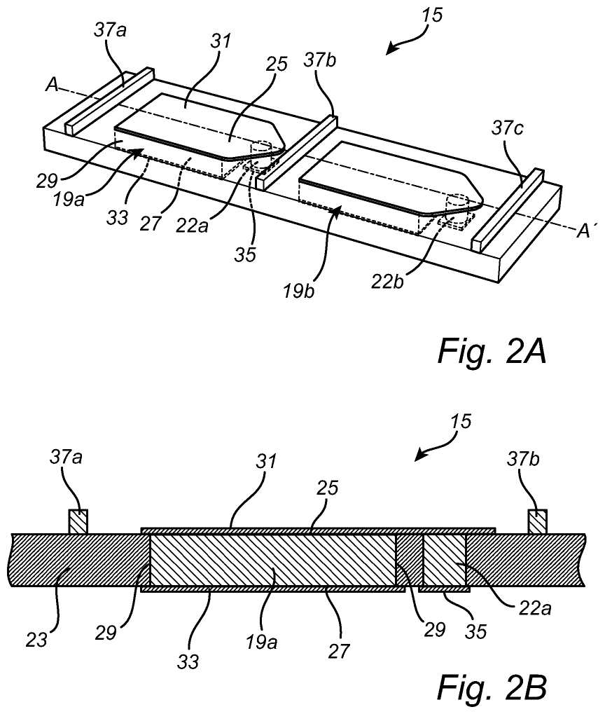

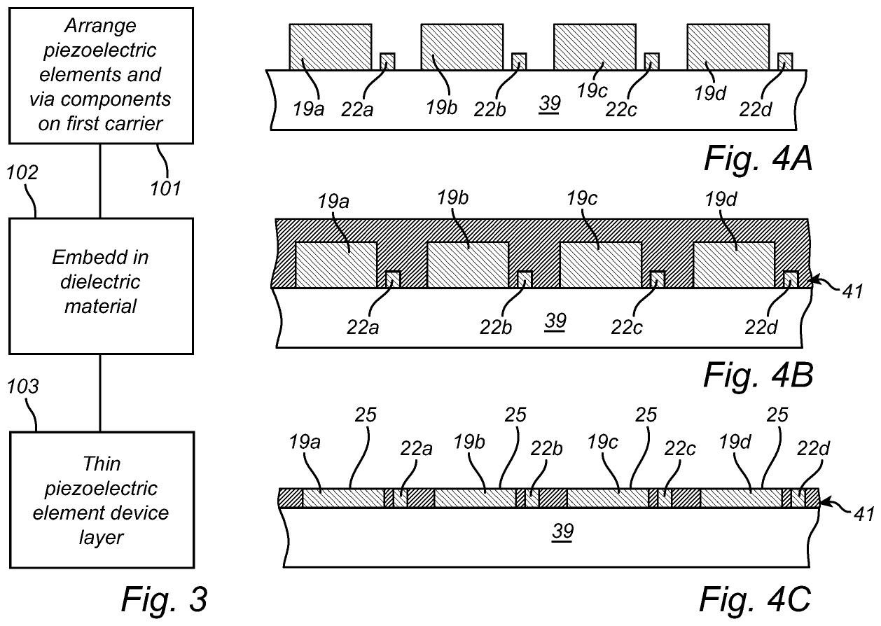

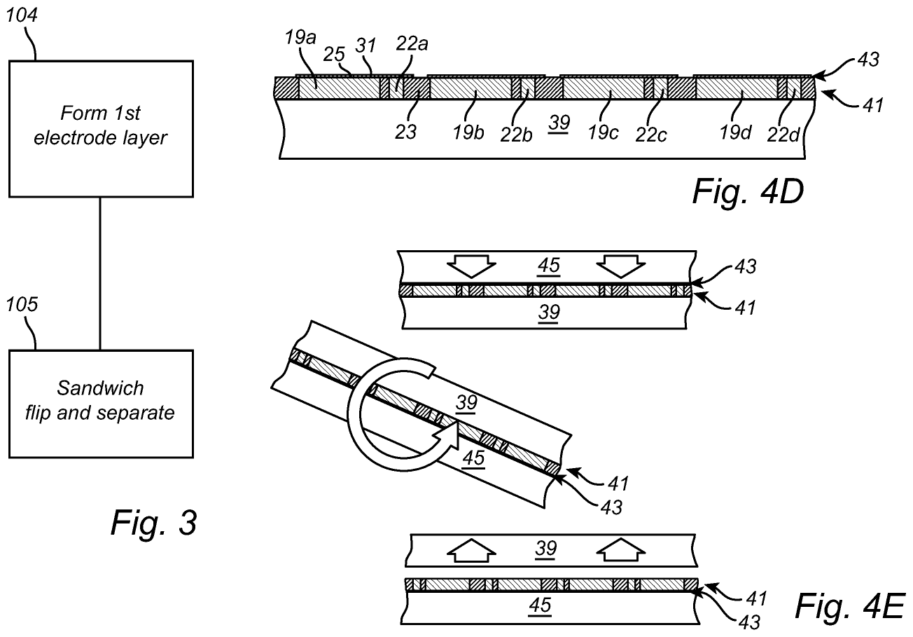

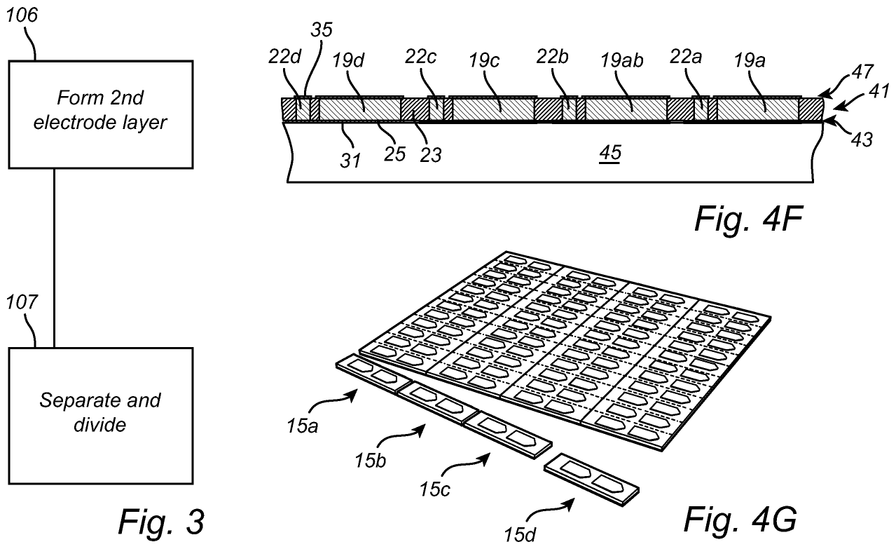

An example of such ultrasonic transducer devices according to an embodiment of the present invention will now be described with reference to FIGS. 2A-B, and a manufacturing method according to an embodiment of the present invention will be described further below with reference to the flow-chart in FIG. 3 and the illustrations in FIGS. 4A-G.

Referring first to FIG. 2A, the ultrasonic transducer device 15 comprises a first piezoelectric element 19a, a second piezoelectric element 19b, a first conductive via 22a, a second conductive via 22b, and a dielectric material 23 embedding the first piezoelectric element 19a, the second piezoelectric element 19b, the first conductive via 22a, and the second conductive via 22b.

As is indicated for the first piezoelectric element 19a, each piezoelectric element has a first face 25, a second face 27, and side edges 29 extending between the first face 25 and the second face 27.

With continued reference to FIG. 2A, the ultrasonic transducer device 15 further comprises a first conductor pattern including, for each piezoelectric element, a first transducer electrode 31 on the first face 25 of the piezoelectric element, and a second conductor pattern, including, for each piezoelectric element, a second transducer electrode 33.

As is schematically indicated in FIG. 2A, the first conductor pattern connects the first transducer electrode 31 with the conductive via 22a, and the second conductor pattern comprises a contact pad 35 connected to the conductive via 22a, in addition to the above-mentioned second transducer electrode 33.

Finally, as was also mentioned further above, the ultrasonic transducer device 15 in FIG. 2A comprises spacer structures 37a-c that are provided outside the area defined by the first face 25 of each the piezoelectric element 19a-b, and that together define a spacer plane parallel with a plane defined by the first face of each piezoelectric element 19a-b, and spaced apart from the first transducer electrode 31 of each piezoelectric element 19a-b. The spacer structures 37a-c are also configured to allow flow of adhesive material from the space between the first transducer electrode 31 of each piezoelectric element 19a-b and the device member to be touched by the user, when the device member (cover glass 11) is attached to the ultrasonic transducer device 15. The spacer structures 37a-c conveniently provide for uniform acoustic coupling between the piezoelectric elements 19a-b (within the ultrasonic transducer device 15 and/or among different ultrasonic transducer devices 15a-e) and the device member (cover glass 11) to be touched by the user.

As may be better seen in the enlarged cross-section view, in a plane of the section taken along the line A-A′ in FIG. 2A, the first transducer electrode 31 can be shaped to directly interconnect the first face 25 of the piezoelectric element 19a with the conductive via 22a. As can also be clearly seen in FIG. 2B, the edges 29 of the piezoelectric element 19a are completely covered by the embedding dielectric material 23, and as the embedding dielectric material 23 and the piezoelectric elements 19a-b have been thinned in the same thinning process, the embedding dielectric material 23 is co-planar with the first face 25 of each piezoelectric element 19a-b, at least at the side edges 29 of piezoelectric elements 19a-b.

An example method of manufacturing the ultrasonic transducer devices 15a-e in FIG. 1B will now be described with reference to the flow-chart in FIG. 3, and the accompanying illustrations in FIGS. 4A-G.

In a first step 101, a plurality of piezoelectric elements 19a-d, and a plurality of conductive via components 22a-d are arranged laterally spaced apart on a temporary first carrier 39. The piezoelectric elements 19a-d may be made of any suitable piezoelectric material, such as for example PZT.

In the subsequent step 102, a dielectric material 23 is applied on the piezoelectric elements 19a-d and on the conductive via components 22a-d to embed the piezoelectric elements 19a-d and the conductive via components 22a-d in the embedding dielectric material 23, thereby forming a piezoelectric element device layer 41.

In the next step 103, the piezoelectric element device layer 41 is thinned, resulting in an exposed first face 25 of each piezoelectric element 19a-d.

Following the thinning step 103, which may be carried out to achieve very thin piezoelectric elements 19a-d (such as less than 100 μm thick) with a very smooth first face 25 (such as with a surface roughness Ra<2 μm), a first electrode layer 43 is formed in step 104. The first electrode layer 43 includes a first transducer electrode 31 on the exposed first face 25 of each piezoelectric element 19a-d in the piezoelectric element device layer 41.

It should be noted that the first electrode layer 43 comprises conductive (such as metal) portions, and may also comprise non-conducting portions provided between the conductive portions. Optionally, spacer structures 37a-c as shown in FIGS. 2A-B can be formed on top of the first electrode layer 41.

In the subsequent step 105, the piezoelectric element device layer 41 and the first electrode layer 43 are sandwiched between the temporary first carrier 39 and a temporary second carrier 45, the “sandwich” is flipped over, and the temporary first carrier 39 is separated from the piezoelectric element device layer 41 and removed, as is indicated in FIG. 4E.

In the next step 106, a second electrode layer 47 is formed, optionally following thinning and/or polishing to achieve a smooth surface structure also on the second face 27 of each piezoelectric element 19a-d. As described above in connection with FIGS. 2A-B, the second electrode layer 47 may comprise, for each of said piezoelectric elements 19a-d, a second transducer electrode on the second face 27, and a contact pad 35 connected to each conductive via 22a-d.

Finally, in step 107, the temporary second carrier 45 is separated from the first electrode layer 43, and the ultrasonic transducer panel is divided into ultrasonic transducer devices 15a-d as is schematically indicated in FIG. 4G.

In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. A method of manufacturing ultrasonic transducer devices for use in an acoustic biometric imaging system, comprising the steps of:
fabricating an ultrasonic transducer panel; and
dividing said ultrasonic transducer panel into said ultrasonic transducer devices,
wherein the step of fabricating said ultrasonic transducer panel comprises the steps of:
providing a first carrier;
arranging a plurality of piezoelectric elements spaced apart on said first carrier;
applying a dielectric material on said plurality of piezoelectric elements to embed each piezoelectric element in said plurality of piezoelectric elements in said dielectric material, thereby forming a piezoelectric element device layer on said first carrier;
thinning said piezoelectric element device layer, resulting in an exposed first side of each piezoelectric element in said plurality of piezoelectric elements;
forming a first electrode layer on said piezoelectric element device layer, said first electrode layer including a first transducer electrode on the exposed first side of each piezoelectric element in said piezoelectric element device layer; and
separating said piezoelectric element device layer from said first carrier.

2. The method according to claim 1, wherein the step of fabricating said ultrasonic transducer panel further comprises the steps of:
sandwiching said piezoelectric element device layer and said first electrode layer between said first carrier and a second carrier; and
forming, after separating said piezoelectric element device layer from said first carrier, a second electrode layer on said piezoelectric element device layer, said second electrode layer including a second transducer electrode on a second side, opposite said first side, of each piezoelectric element in said piezoelectric element device layer.

3. The method according to claim 2, wherein the step of fabricating said ultrasonic transducer panel further comprises the step of:
thinning, after separating said piezoelectric element device layer from said first carrier and before forming said second electrode layer, said piezoelectric element device layer.

4. The method according to claim 2 or 3, wherein the step of fabricating said ultrasonic transducer panel further comprises the step of:
providing a plurality of conductive vias through said piezoelectric element layer.

5. The method according to claim 4, wherein said second electrode layer is formed in such a way that each second transducer electrode is conductively connected to at least one conductive via in said plurality of conductive vias.

6. The method according to claim 1, wherein the step of fabricating said ultrasonic transducer panel further comprises the step of:
providing a plurality of conductive vias through said piezoelectric element layer.

7. The method according to claim 6, wherein said first electrode layer is formed in such a way that each first transducer electrode is conductively connected to at least one conductive via in said plurality of conductive vias.

8. The method according to claim 1, wherein the step of fabricating said ultrasonic transducer panel further comprises the step of:
forming, after the step of forming said first electrode layer, a spacer structure leaving at least a portion of each of said first transducer electrodes uncovered.

9. The method according to claim 1, wherein said ultrasonic transducer panel is divided by cutting through said dielectric material embedding said plurality of piezoelectric elements.

10. An ultrasonic transducer device for use in an acoustic biometric imaging system, said ultrasonic transducer device comprising:
a piezoelectric element having a first face, a second face opposite said first face, and side edges extending between said first face and said second face;
a first transducer electrode on the first face of said piezoelectric element;
a second transducer electrode on the second face of said piezoelectric element; and
a dielectric material embedding said piezoelectric element in such a way that said side edges are completely covered by said dielectric material.

11. The ultrasonic transducer device according to claim 10, wherein at least one of said first transducer electrode and said second transducer electrode partly covers said dielectric material embedding said piezoelectric element.

12. The ultrasonic transducer device according to claim 10, wherein said dielectric material embedding said piezoelectric element is co-planar with the first face of said piezoelectric element, at least at the side edges of said piezoelectric element.

13. The ultrasonic transducer device according to claim 10, wherein said dielectric material embedding said piezoelectric element and said piezoelectric element have been thinned in the same thinning process.

14. The ultrasonic transducer device according to claim 10, wherein said ultrasonic transducer device comprises:
a plurality of piezoelectric elements, each having a first face, a second face opposite said first face, and side edges extending between said first face and said second face;
a first transducer electrode on the first face of each piezoelectric element in said plurality of said piezoelectric elements;
a second transducer electrode on the second face of each piezoelectric element in said plurality of said piezoelectric elements; and
at least one integrated circuit electrically connected to at least one of the first transducer electrode and the second transducer electrode of at least one piezoelectric element in said plurality of piezoelectric elements,
wherein said dielectric material embeds said integrated circuit, and embeds said plurality of piezoelectric element in such a way that said side edges of each piezoelectric element in said plurality of said piezoelectric elements are completely covered by said dielectric material.

15. An acoustic biometric imaging system comprising:
at least one ultrasonic transducer device according to claim 10 to be acoustically coupled to a device member to be touched by a finger surface of a user; and
a controller connected to said at least one ultrasonic transducer device and being configured to:
receive, from said at least one ultrasonic transducer device, electrical signals indicative of acoustic signals conducted by said device member and acoustically coupled to said at least one ultrasonic transducer device; and
form a representation of said finger surface based on said received electrical signals.
